(19) United States
(12) Patent Application Publication
(10) Pub. No.: US 2009/0045432 A1
(43) Pub. Date: Feb. 19, 2009

(54) Circuit board for light emitting device package and light emitting unit using the same

(76) Inventors: Yong Suk Kim, Seoul (KR); Bu Wan Seo, Seoul (KR); Hoon Hur, Gyeonggi-do (KR)

Correspondence Address: MCKENNA LONG & ALDRIDGE LLP, 1900 K STREET, NW, WASHINGTON, DC, 20006, US

(21) Appl. No.: 12/222,595

(22) Filed: Aug. 12, 2008

(30) Foreign Application Priority Data
Aug. 13, 2007 (KR) 10-2007-0081288
Jan. 7, 2008 (KR) 10-2008-0001715

(51) Int. Cl. H01L 23/00

(52) U.S. Cl. 257/99; 257/E23.001

(57) ABSTRACT

A circuit board for a light emitting device and a light emitting unit using the same, which are capable of achieving an enhancement in light emission efficiency and an enhancement in reliability, are disclosed. The disclosed circuit board includes a substrate having a first surface and a second surface, at least one pair of conductive lines formed on the first surface of the substrate, and electrically connected to a light emitting device package, and a heat transfer member formed in a region where the light emitting device package is coupled to the circuit board, such that the heat transfer member connects the first and second surfaces of the substrate.

This application claims the benefit of Korean Patent Application No. 10-2007-0081288, filed on Aug. 13, 2007 and Korean Patent Application No. 10-2008-0001715, filed on Jan. 7, 2008, which are hereby incorporated by references as if fully set forth herein.

### BACKGROUND OF THE INVENTION

1. Field of the Invention

The present invention relates to a circuit board for a light emitting device and a light emitting unit using the same, and more particularly, to a circuit board for a light emitting device and a light emitting unit using the same, which are capable of achieving an enhancement in light emission efficiency and an enhancement in reliability.

2. Discussion of the Related Art

Light emitting diodes (LEDs) are well known as a semiconductor light emitting device which converts current to light. Since a red LED using GaAsP compound semiconductor was commercially available in 1962, it has been used, together with a GaP:N-based green LED, as a light source in electronic apparatuses including information communication appliances, for image display.

The wavelength of light emitted from such an LED depends on the semiconductor material used to fabricate the LED. This is because the wavelength of the emitted light depends on the band gap of the semiconductor material representing energy difference between valence-band electrons and conduction-band electrons.

Gallium nitride (GaN) compound semiconductor has been highlighted in the field of high-power electronic devices because it exhibits a high thermal stability and a wide band gap of 0.8 to 6.2 eV.

One of the reasons why GaN compound semiconductor has been highlighted is that it is possible to fabricate a semiconductor layer capable of emitting green, blue, or white light, using GaN in combination with other elements, for example, indium (In), aluminum (Al), etc.

Thus, it is possible to adjust the wavelength of light to be emitted, using GaN in combination with other appropriate elements. Accordingly, where GaN is used, it is possible to appropriately determine the materials of a desired LED in accordance with the characteristics of the apparatus to which the LED is applied. For example, it is possible to fabricate a blue LED useful for optical recording or a white LED to replace a glow lamp.

By virtue of the above-mentioned advantages and other advantages of GaN-based LEDS, the GaN-based LED market h a s rapidly grown. Also, techniques associated with GaN-based electro-optic devices have rapidly developed since the GaN-based LEDs became commercially available in 1994.

In order to manufacture light emitting device products using such LEDs, it is necessary to use a circuit board, in particular, a printed circuit board (PCB), on which LEDs will be mounted.

Such a PCB not only functions to connect circuits respectively included in a plurality of LEDs, but also functions to transfer heat discharged from the LED's to a secondary heat discharge system or to the air.

In order to apply LEDs to a certain product, it is necessary to manufacture a light emitting unit by preparing LED modules each including PCBs, on which a plurality of LEDs are mounted.

### SUMMARY OF THE INVENTION

Accordingly, the present invention is directed to a circuit board for a light emitting device and a light emitting unit using the same that substantially obviate one or more problems due to limitations and disadvantages of the related art.

An object of the present invention is to provide a circuit board for a light emitting device, which has a simple structure capable of achieving an excellent heat discharge efficiency and an inexpensive manufacture process, and a light emitting unit using the circuit board, which has high reliability.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a circuit board for a light emitting device comprises: a substrate having a first surface and a second surface; at least one pair of conductive lines formed on the first surface of the substrate, and electrically connected to a light emitting device package; and a heat transfer member formed in a region where the light emitting device package is coupled to the circuit board, such that the heat transfer member connects the first and second surfaces of the substrate.

In another aspect of the present invention, a light emitting unit comprises: a substrate having a first surface and a second surface; at least one pair of conductive lines formed on the first surface of the substrate, and electrically connected to a light emitting device package; a heat transfer member formed such that the heat transfer member connects the first and second surfaces of the substrate; and the light emitting device package arranged on the heat transfer member such that the light emitting device package is electrically connected to the conductive lines.

In another aspect of the present invention, a light emitting unit comprises: a substrate having a first surface, a second surface, and at least one through hole extending through the first and second surfaces; at least one pair of conductive lines formed on the first surface of the substrate; a light emitting device package arranged on the first surface of the substrate; and a solder formed to electrically connect the light emitting device package to the conductive lines, and to fill the through hole.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view illustrating an example of a flame retardant-4 (FR4) printed circuit board (PCB);

FIG. 2 is a sectional view illustrating an example of a metal core PCB (MCPCB);

FIGS. 3 to 8 are sectional views illustrating a first embodiment of the present invention;

FIGS. 9 to 11 are sectional views illustrating a second embodiment of the present invention; and

FIGS. 12 to 17 are sectional views illustrating a third embodiment of the present invention.

### DETAILED DESCRIPTION OF THE INVENTION

Reference will now be made in detail to the preferred embodiments of the present invention, examples of which are illustrated in the accompanying drawings.

The present invention may, however, be embodied in many alternate forms and should not be construed as limited to the embodiments set forth herein. Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims.

Like numbers refer to like elements throughout the description of the figures. In the drawings, the thickness of layers and regions are exaggerated for clarity.

It will be understood that when an element such as a layer, region or substrate is referred to as being “on” another element, it can be directly on the other element or intervening elements may also be present. It will also be understood that if part of an element, such as a surface, is referred to as “inner,” it is farther to the inside of the device than other parts of the element.

In addition, relative terms, such as “beneath” and “overlies”, may be used herein to describe one layer's or region's relationship to another layer or region as illustrated in the figures.

It will be understood that these terms are intended to encompass different orientations of the device in addition to the orientation depicted in the figures. Finally, the term “directly” means that there are no intervening elements. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms.

These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

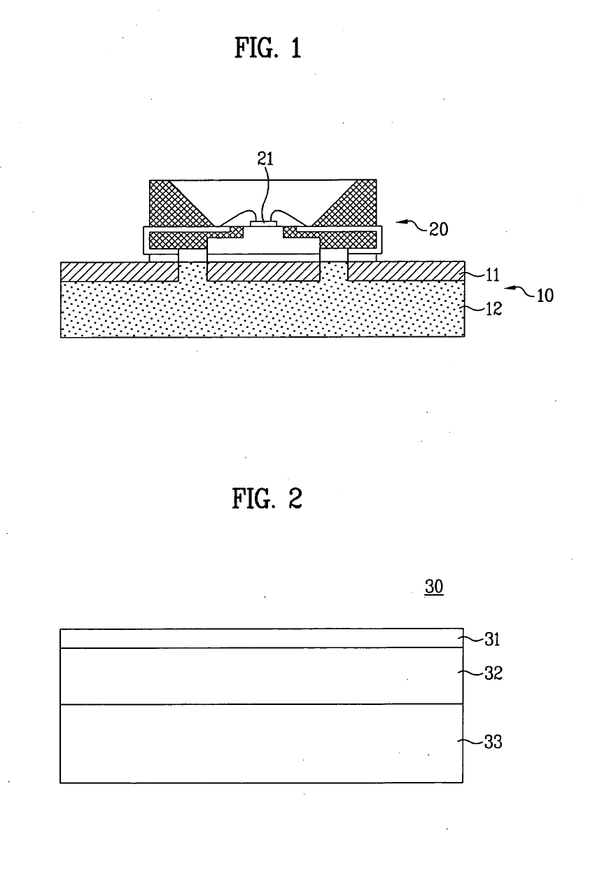

For a circuit board or a printed circuit board (PCB), which may be coupled to a light emitting device package, to be used in the manufacture of a light emitting unit, a flame retardant-4 (FR4) PCB 10 as shown in FIG. 1, a flexible PCB (FPCB), or a metal core PCB (MCPCB) 30 can be used.

In the case of the FR4 PCB 10, a copper (Cu) layer 11 is arranged beneath a light emitting device package 20. In order to insulate the copper layer 11 from a structure, which will be arranged beneath the PCB 10, an insulating substrate 12 is also provided.

In the light emitting device package 20, heat is generated from a light emitting device chip 21 arranged at a central portion of the light emitting device package 20. The generated heat does not flow toward the top of the chip 21, but flows toward the PCB 10, namely, toward the bottom of the chip 21.

In the FR4 PCB 10 as described above, heat generated at the bottom of the light emitting device chip 21 may flow up to the copper layer 11. However, the generated heat may not easily be transferred to the FR4. insulating substrate 12.

Referring to Table 1, it can be seen that a gradual reduction in thermal conductivity is exhibited in the order of copper, which is a medium having a highest thermal conductivity, aluminum, and FR4. As shown in Table 1, the thermal conductivity difference between copper and FR4 is about 1,000 times, As a result, in the FR4 PCB 10, which has a general structure as shown in FIG. 1, heat generated from the light emitting device chip 21 may be confined in the copper layer 11, even though the generated heat can rapidly be transferred up to the copper layer 11. This is because the FR4 insulating substrate 12 has a very low thermal conductivity.

TABLE 1

| Item | Thermal Conductivity |
|---|---|
| Unit | W/mK (Heat Discharge Quantity) |
| Copper | 400 |
| Aluminum 5052 | 137 |
| FR4 | 0.4 |
| Epoxy-Ceramic Filter | 12 |
| (Insulating Layer) | |

Similarly, in the case of the MCPCB 30, in which a thick aluminum layer 33 is arranged at the bottom of the MCPCB 30, as shown in FIG. 2, heat confined in an insulating layer 32 can be rapidly transferred to the aluminum layer 22. However, although the heat can be effectively transferred up to a copper layer 31, it may be confined in the insulating layer 32.

Furthermore, in the MCPCB 30, there are disadvantages of a difficulty in manufacturing a multilayer circuit structure and relatively-high manufacturing costs, as compared to FR4 and FPCB.

In the case of a light emitting device package exhibiting general consumption power of about 0.1 W, a light emitting unit or light emitting device package module thereof can be manufactured using the FR4 PCB. This is because the light emitting device package exhibits low consumption power, so that the quantity of heat discharged from the light emitting unit or light emitting device package module thereof is not excessive.

Recently, the application field of such a light emitting device package has been extended to the field associated with a high power chip for high brightness. This is because the application field has been extended from indirect illumination to direct illumination, so that the use of high power light emitting devices has increased.

In the case of a module using such a high-brightness light emitting device, an MCPCB is mainly used. However, it may be difficult to achieve the use of the MCPCB because the MCPCB is expensive, and is difficult to configure a complex circuit.

In the following embodiments, a circuit board usable to manufacture a high-power light emitting device and a package thereof, which are usable to manufacture a light emitting unit, and a manufacturing method for the circuit board will be described.

### First Embodiment

Referring to FIG. 3, a circuit board 100 according to a first embodiment of the present invention is illustrated. The circuit board 100 includes a substrate 110 made of an insulating material, at least one pair of conductive lines 120 connected to a light emitting device package 200, and a heat transfer member 130 coupled to the light emitting device package 200.

As shown in FIG. 3, the conductive lines 120 are formed on an upper surface of the substrate 110 such that they are electrically connected with the light emitting device package 200. A metal plate 140 may be formed on a lower surface of the substrate 110 such that it is in contact with the heat transfer member 130.

The heat transfer member 130, which is thermally coupled with the light emitting device package 200, may be in direct contact with the light emitting device package 200, or may be connected to the light emitting device package 200 via a thermal coupler 210 such as a thermal grease or solder. The thermal coupler 210 may be coupled with a heat sink or heat slug 220 of the light emitting device package 200.

The light emitting device package 200 also includes electrodes 230, which may be electrically connected to respective conductive lines 120 by a material such as a solder 231.

The heat transfer member 130 may be formed such that it extends vertically through the substrate 110. FIG. 3 illustrates an embodiment in which the heat transfer member 130 comprises a pillar member 131 made of a metal having an excellent thermal conductivity, such as copper (Cu). The heat transfer member 130, which comprises the pillar member. 131, may have a circular or polygonal pillar shape.

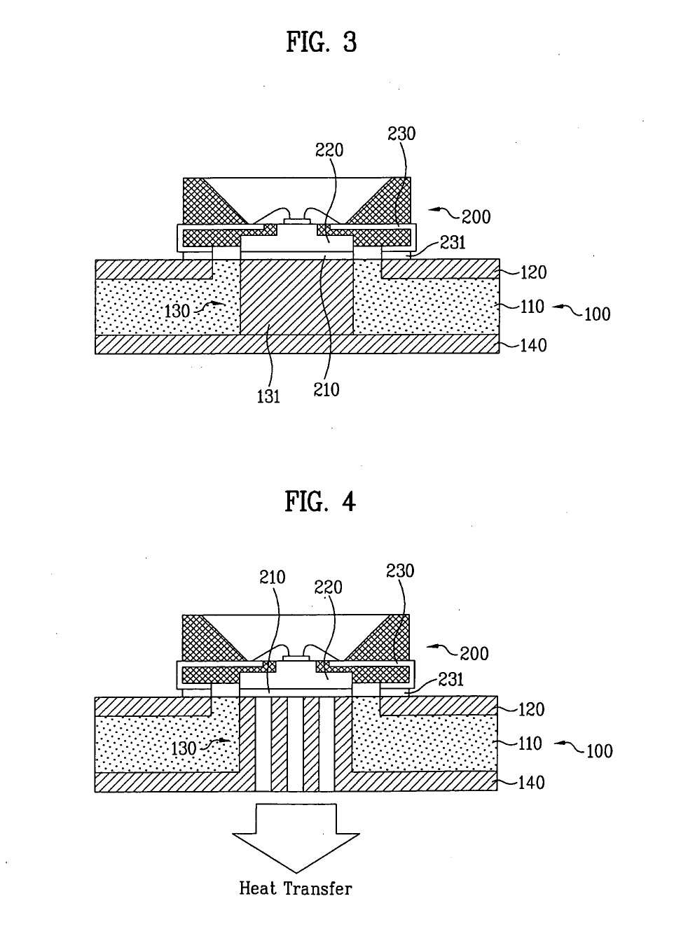

As shown in FIG. 4, heat discharged from the bottom of the light emitting device package 200 via the heat transfer member 130 made of a metal having an excellent thermal conductivity, such as copper, is transferred to the bottom of the circuit board 100 without passing through the insulating material of the substrate 110. Accordingly, there is an advantage in that a large quantity of heat can be effectively discharged through a secondary heat discharge system (not shown) provided at the circuit board 100 within a short time.

The circuit board 100, which includes the above-described heat transfer member 130, is manufactured in accordance with the following procedure.

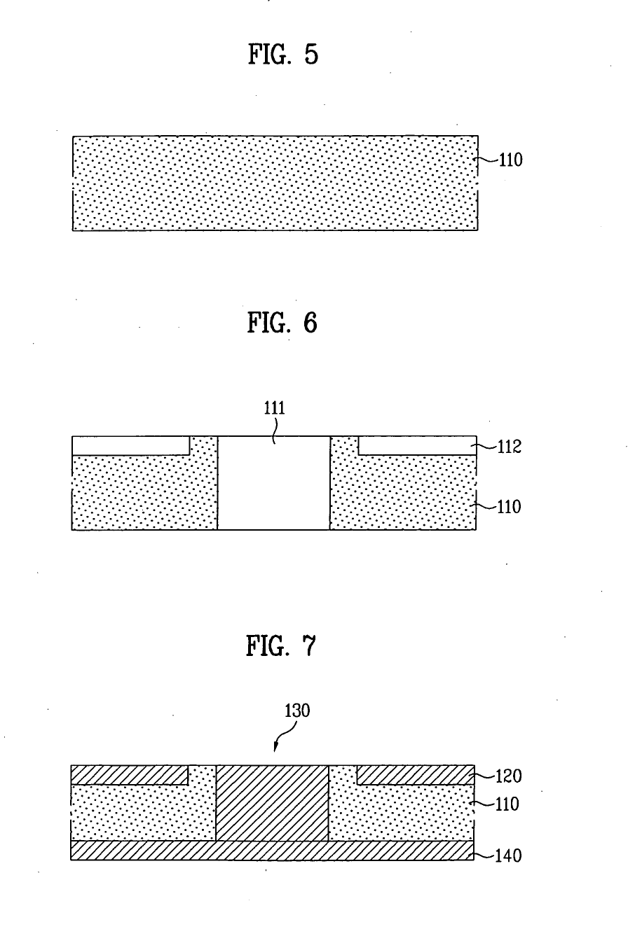

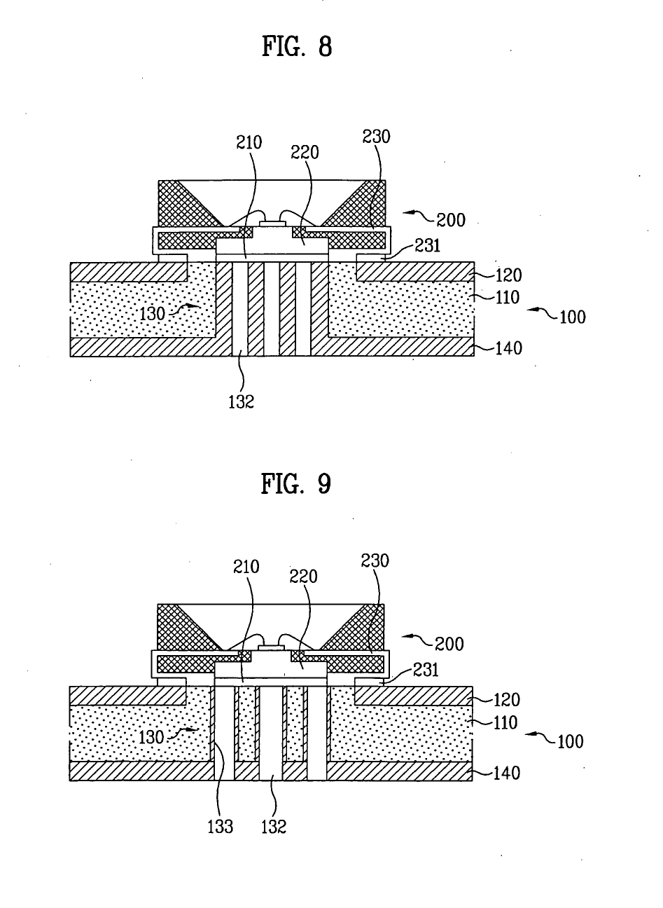

First, the insulating substrate 110 is prepared, as shown in FIG. 5. Thereafter, the insulating substrate 110 is patterned in accordance with an etching method or a drilling method, in order to form metal patterns. That is, a hole 111 is formed through a central portion of the insulating substrate 110 where the heat transfer member 130 will be formed, as shown in FIG. 6. Grooves 112 are also formed at the upper surface of the insulating substrate 110, for the formation of the conductive lines 120.

A metal such as copper fills the hole 111 and grooves 112, to manufacture a circuit board structure as shown in FIG. 7.

If necessary, the conductive lines 120 may be formed by etching a metal plate previously formed over the insulating substrate 110.

In the case in which the light emitting device package 200 has heat generation characteristics exhibiting low heat generation, through holes 132 may be formed through the heat transfer member 130. The through holes 132 function to cause the light emitting device package 200 or the heat sink 220 thereof to come into contact with air, or to be connected with the secondary heat discharge system via a flow of air.

### Second Embodiment

Referring to FIG. 9, a circuit board 100 according to a second embodiment of the present invention is illustrated. The circuit board 100 includes a substrate 110 made of an insulating material, at least one pair of conductive lines 120 connected to a light emitting device package 200, and a heat transfer member 130 coupled to the light emitting device package 200. In accordance with this embodiment, the heat transfer member 130 includes a plurality of through holes 132.

As shown in FIG. 9, the conductive lines 120 are formed on an upper surface of the substrate 110 such that they are electrically connected with the light emitting device package 200. A metal plate 140 may be formed on a lower surface of the substrate 110 such that it is in contact with the heat transfer member 130. The above-described configurations are identical to those of the first embodiment.

In this embodiment, namely, the second embodiment, the through holes 132 of the heat transfer member 130 extend vertically through the substrate 110. A metal film 133 made of a metal having an excellent thermal conductivity, such as copper, may also be plated on the inner surfaces of the through holes 132.

Even when the heat transfer member 130 is not configured such that a metal completely fills a region beneath the light emitting device package 200, but configured such that the metal film 133 is plated only on the inner surfaces of the through holes 132, the latter configuration can have effects substantially identical to those of the former configuration.

That is, the light emitting device package 200 or the heat sink 220 thereof is in direct contact with the heat transfer member 130 or is connected to the heat transfer member 130 via a thermal coupler 210. Accordingly, heat generated from the light emitting device is transferred to the heat transfer member 130. In this case, the transferred heat can be rapidly transferred to the bottom of the circuit board 100 along the metal film 133 formed in the through holes 132.

The metal film 133 may have a thermal conductivity sufficient to transfer heat generated from the light emitting device.

In this case, the portion of each through hole 132 where the metal film 133 is not present may form an air path. This through hole portion may also form a path connected to a secondary heat discharge system provided at the circuit board 100.

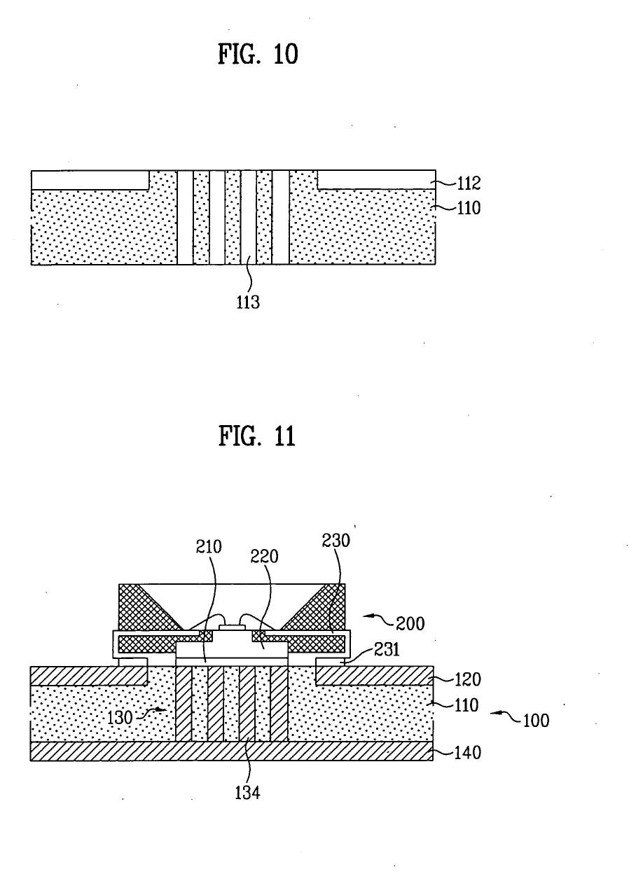

The circuit board 100 configured as described above is manufactured in accordance with the following procedure. That is, as shown in. FIG. 10, a plurality of through holes 113 are formed through the insulating substrate 110 in a region where the light emitting device package 200 is coupled to the insulating substrate 110. Also, grooves 112 are formed at the upper surface of the insulating substrate 110, for the formation of the conductive lines 120.

Through the above-described procedures, it is possible to manufacture the circuit board 100 as shown in FIG. 9.

If necessary, the entire portion of each through hole 113 may be filled with a metal, in order to obtain a structure as shown in FIG. 11, in place of the case in which the metal film 133 is formed at each through hole 113. In this case, the metal filling each hole 113 may constitute a metal pillar 134, which enables the heat transfer member 130 to achieve effective heat transfer.

### Third Embodiment

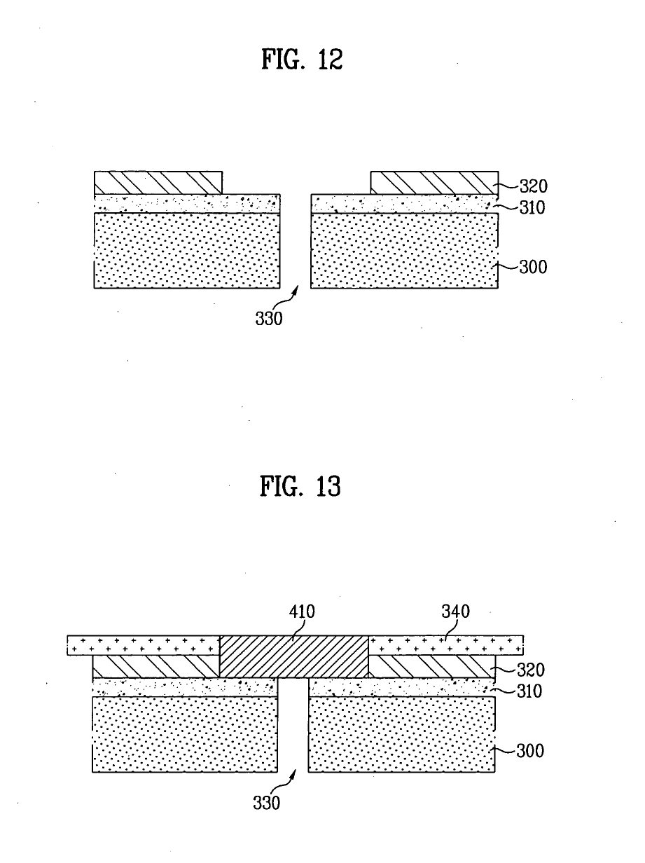

Hereinafter, a third embodiment of the present invention will be described with reference to FIGS. 12 to 17.

In order to manufacture a circuit board according to the third embodiment, as shown in FIG. 12, at least one pair of conductive lines 310 are formed on a substrate 300. An insulating layer 320 is arranged on the conductive lines 310. Each conductive line 310 is comprised of a metal pattern such as a copper pattern. The insulating layer 320 may be made of a material such as a solder resist or paint.

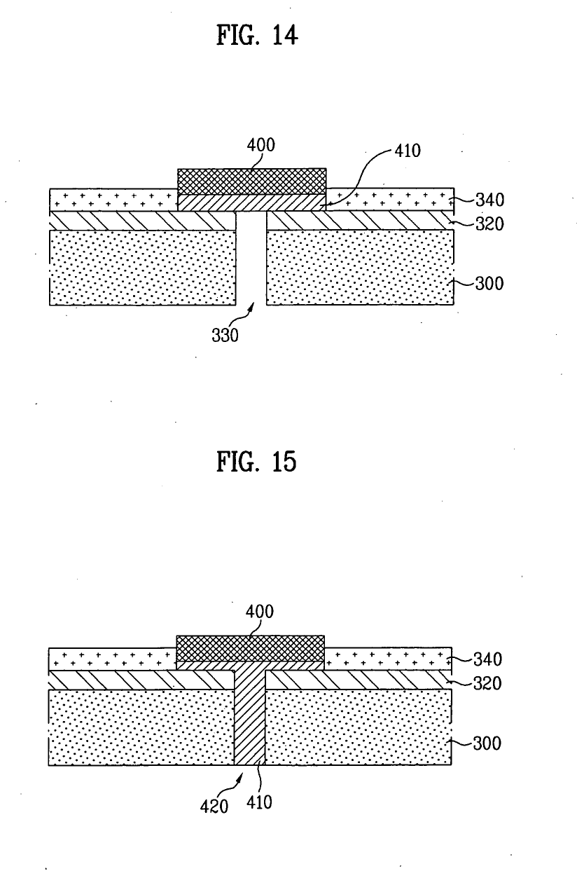

The insulating layer 320 is arranged on the conductive lines 310 in regions other than a region where a light emitting device package 400 (FIG. 14) will be mounted. That is, the insulating layer 320 is arranged in regions other than a region where a solder (lead) is coated to mount the light emitting device package 400.

A through hole 330 is formed through the substrate 300 and conductive lines 310 in a region where the light emitting device package 400 will be mounted, such that the through hole 330 extends vertically. The through hole 330 may constitute a heat transfer member 420 (FIG. 15) to effectively discharge heat emitted from the light emitting device package 400.

The through hole 330 may be formed in plural beneath the region where the light emitting device package 400 will be mounted. The plurality of through holes 330 may form a particular pattern. For example, the through holes 330 may be patterned to form a triangular or square lattice structure.

Meanwhile, the insulating layer 320 may not be coated on a lower surface of the substrate 300. This is because a solder, which is coated on the lower surface of the substrate 300, fills an empty space of each through hole 330 without any interference as it is melted due to high-temperature heat during a reflow process subsequently carried out to mount the light emitting device package 400, so that it functions to fix the light emitting device package 400 to the circuit board.

Hereinafter, a procedure for manufacturing a light emitting unit by mounting the light emitting device package 400 on the circuit board manufactured as described above will be described.

First, as shown in FIG. 13, a solder 410 is coated on the mounting region for the light emitting device package 400, using a metal mask 340. The coating of the solder 410 may be achieved using a solder printer.

As described above, the insulating layer 320 may not be arranged on the substrate 300 in a region where the through hole 330 is not formed. The solder 410 is arranged over the through hole 330.

Thereafter, the light emitting device package 400 is placed on the coated solder 410, using surface mounting equipment or the like, as shown in FIG. 14.

A reflow process is subsequently carried out, as shown in FIG. 15. As the circuit board passes through a furnace maintained at high temperature during the reflow process, the coated solder 410 is melted, so that it electrically connects the light emitting device packager 400 to the conductive lines 310.

During the above-described reflow process, the solder 410 flows along the metal surfaces of the conductive lines 320 around the top of the through hole 330, so that it fills the through hole 330.

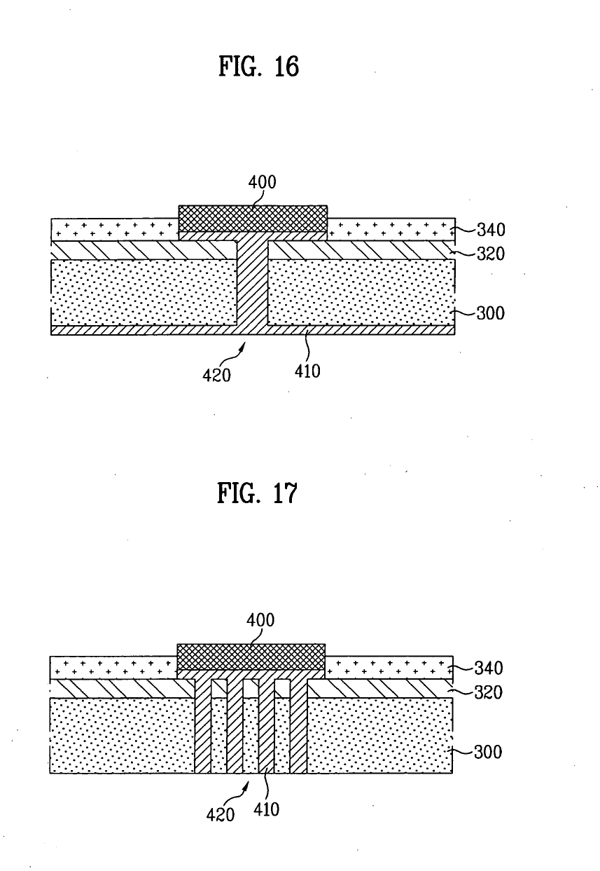

In accordance with this reflow process, the solder 410 may reach and cover the lower surface of the substrate 300, as shown in FIG. 16.

Meanwhile, the through hole 330 may be provided in plural, as shown in FIG. 17. In this case, all the through holes 330 may be filled with the solder 410 in the above-described reflow process.

The above-described structure has the following advantages. That is, the top and bottom of the circuit board are connected with each other via the through hole 330. Since the solder 410 fills the through hole 330 in the reflow process, the resultant structure has a performance greatly excellent in terms of thermal conductivity.

Since the solder 410 has a thermal conductivity of about 250 W/mK, the above-described structure may be inferior to the case, in which copper (Cu) (Cu has a thermal conductivity of 400 W/mK) fills the through hole, as in the first and second embodiments. However, there is an advantage in that it is possible to inexpensively provide an excellent thermal conductivity without any particular additional process.

This is because, since the most expensive one of the materials used in the circuit board is copper, it is possible to manufacture a circuit board and a light emitting unit thereof, which are greatly excellent in terms of economy, when the through hole 330 is filled with the solder 410, in place of copper.

Since the same substrate as the FR4 circuit board (PCB) can be used for the substrate 300, as described above, the circuit board of the present invention can have a greatly-enhanced thermal conductivity, and thus, a stable performance, while having price competitiveness in that it can be inexpensively manufactured, similarly to the general circuit board.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A circuit board for a light emitting device comprising:
a substrate having a first surface and a second surface;
at least one pair of conductive lines formed on the first surface of the substrate, and electrically connected to a light emitting device package; and
a heat transfer member formed in a region where the light emitting device package is coupled to the circuit board, such that the heat transfer member connects the first and second surfaces of the substrate.

2. The circuit board according to claim 1, wherein the heat transfer member comprises at least one metal pillar extending through the substrate.

3. The circuit board according to claim 2, wherein the metal pillar is formed with at least one through hole, which extends vertically.

4. The circuit board according to claim 1, wherein the heat transfer member comprises at least one through hole formed through the substrate such that the through hole extends vertically.

5. The circuit board according to claim 4, wherein a metal is plated on an inner surface of the through hole.

6. The circuit board according to claim 1, wherein a metal layer is formed over the second surface of the substrate.

7. The circuit board according to claim 2, wherein the metal pillar is made of copper or lead.

8. The circuit board according to claim 1, further comprising:
an insulating layer formed on the conductive lines.

9. A light emitting unit comprising:
a substrate having a first surface and a second surface;
at least one pair of conductive lines formed on the first surface of the substrate, and electrically connected to a light emitting device package;
a heat transfer member formed such that the heat transfer member connects the first and second surfaces of the substrate; and
the light emitting device package arranged on the heat transfer member such that the light emitting device package is electrically connected to the conductive lines.

10. The light emitting unit according to claim 9, wherein the light emitting device package includes a heat sink, which is in contact with a light emitting device.

11. The light emitting unit according to claim 10, wherein the heat sink is in contact with the heat transfer member.

12. The light emitting unit according to claim 9, further comprising:
a metal layer arranged on the second surface of the substrate.

13. The light emitting unit according to claim 9, wherein the heat transfer member comprises at least one metal pillar or a through hole, which extends through the substrate.

14. The light emitting unit according to claim 13, wherein the through hole is filled with copper or lead.

15. The light emitting unit according to claim 13, further comprising:
an insulating layer arranged on the conductive lines outside the light emitting device package.

16. A light emitting unit comprising:
a substrate having a first surface, a second surface, and at least one through hole extending through the first and second surfaces;
at least one pair of conductive lines formed on the first surface of the substrate;
a light emitting device package arranged on the first surface of the substrate; and
a solder formed to electrically connect the light emitting device package to the conductive lines, and to fill the through hole.

17. The light emitting unit according to claim 16, wherein the solder is formed in accordance with a reflow process to electrically connect the light emitting device package to-the conductive lines, and to fill the through hole.

18. The light emitting unit according to claim 16, further comprising:
an insulating layer arranged on the substrate.

19. The light emitting unit according to claim 18, wherein the through hole extends through the substrate and the insulating layer.

20. The light emitting unit according to claim 16, further comprising:
a metal mask arranged on the substrate.
